(19) United States
(12) Patent Application Publication
(10) Pub. No.: US 2013/0249645 A1
(43) Pub. Date: Sep. 26, 2013

(54) NON-MAGNETIC COMPOSITION FOR CERAMIC ELECTRONIC COMPONENT, CERAMIC ELECTRONIC COMPONENT USING THE SAME, AND METHOD OF MANUFACTURING THE SAME

(71) Applicants: Ho Yoon KIM, Suwon (KR); Min Kyoung Cheon, Suwon (KR); Sung Yong An, Suwon (KR); Young Il Lee, Suwon (KR); Myeong Gi Kim, Suwon (KR)

(72) Inventors: Ho Yoon KIM, Suwon (KR); Min Kyoung Cheon, Suwon (KR); Sung Yong An, Suwon (KR); Young Il Lee, Suwon (KR); Myeong Gi Kim, Suwon (KR)

(73) Assignee: Samsung Electro-Mechanics Co., Ltd.

(21) Appl. No.: 13/538,451

(22) Filed: Jun. 29, 2012

(30) Foreign Application Priority Data
Mar. 22, 2012 (KR) 10-2012-0029345

(51) Int. Cl. H03H 7/01; B32B 37/14; B32B 37/02; H01F 27/02; C04B 35/45

(52) U.S. Cl. 333/175; 336/90; 501/1; 156/89.12

(57) ABSTRACT

There are provided a non-magnetic composition for a ceramic electronic component, a ceramic electronic component using the same, and a method of manufacturing the same. The non-magnetic composition includes a compound represented by Chemical Formula Zn₁₋ₓCuₓMn₂O₄. Therefore, DC bias characteristics of the ceramic electronic component may be improved by employing the non-magnetic composition having no magnetic characteristics.

### CROSS-REFERENCE TO RELATED APPLICATIONS

This application claims the priority of Korean Patent Application No. 10-2012-0029345 filed on Mar. 22, 2012, in the Korean Intellectual Property Office, the disclosure of which is incorporated herein by reference.

### BACKGROUND OF THE INVENTION

1. Field of the Invention

The present invention relates to a non-magnetic composition for a ceramic electronic component capable of improving bias characteristics in the ceramic electronic component, a ceramic electronic component using the same, and a method of manufacturing the same.

2. Description of the Related Art

An inductor is a main passive element in an electronic circuit, along with a resistor and a capacitor, and may be used in an LC resonance circuit or as a circuit component for removing noise.

An inductor may be manufactured by winding or printing a coil on a ferrite core and forming electrodes at both ends thereof, or by printing inner electrodes on magnetic or dielectric material sheets and stacking the sheets.

The inductors are classified into several types, such as a lamination-type, a winding-type, a thin film-type, and the like, and among these, the lamination-type inductor is widely employed.

The lamination-type inductor includes a plurality of magnetic sheets (formed of ferrite or a low-k dielectric material).

Coil type conductive patterns are formed on the magnetic sheets, and these coil type conductive patterns respectively formed on the magnetic sheets constitute internal electrodes.

These internal electrodes are provided in series and are electrically connected to one another through via electrodes formed in the ferrite sheets.

This lamination-type inductor may be manufactured as a separate chip type component, or may be formed together with other modules while it is embedded in a board.

Generally, the lamination-type inductor has a structure in which a plurality of magnetic layers having conductive patterns printed thereon are laminated. The conductive patterns are sequentially connected by via electrodes formed in the respective magnetic layers so that they overlap in a lamination direction, resulting in a coil having a helical structure.

In addition, both ends of the coil may be drawn to an external surface of the laminate and connected to external terminals.

As such, since the coil is surrounded by a magnetic material such as ferrite in the lamination-type inductor, the magnetic material around the coil tends to be magnetized at the time of the application of relatively high current.

In addition, the surroundings of the coil are magnetized, causing a change in an inductance (L) value of the inductor, and thereby deteriorating inductance characteristics of the inductor.

The related art document below is provided to attempt to solve the above defects by inserting a non-magnetic layer formed of a copper-zinc (Cu—Zn)-based ferrite between magnetic layers. However, the difference in a shrinkage ratio between a basic ferrite material and the non-magnetic layer at the time of sintering may cause a high risk of delamination, and bias-TCL characteristics may be degraded by being diffused in the non-magnetic layer.

### [Related Art Document]

Japanese Patent Laid-Open Publication No. 2003-124028

### SUMMARY OF THE INVENTION

An aspect of the present invention provides a non-magnetic composition for a ceramic electronic component capable of improving bias characteristics in the ceramic electronic component, a ceramic electronic component using the same, and a method of manufacturing the same.

According to an aspect of the present invention, there is provided a non-magnetic composition for a ceramic electronic component, the non-magnetic composition including a compound represented by Chemical Formula Zn₁₋ₓCuₓMn₂O₄.

The compound may have a spinel-type crystal structure.

The compound may be prepared by mixing 40 to 50 mole % of manganese oxide (Mn₃O₄), 30 to 45 mole % of copper oxide (CuO), and 10 to 25 mole % of zinc oxide (ZnO).

According to another aspect of the present invention, there is provided a ceramic electronic component, including: a ceramic body having a plurality of magnetic layers laminated therein; internal electrode layers formed within the ceramic body; a non-magnetic layer interposed between the magnetic layers and containing a compound represented by Chemical Formula Zn₁₋ₓCuₓMn₂O₄; and external electrodes formed on the exterior of the ceramic body and electrically connected to the internal electrode layers.

The compound may have a spinel-type crystal structure.

The compound may be prepared by mixing 40 to 50 mole % of manganese oxide (Mn₃O₄), 30 to 45 mole % of copper oxide (CuO), and 10 to 25 mole % of zinc oxide (ZnO).

The internal electrode may contain silver (Ag) or copper (Cu), and the external electrode may contain silver (Ag) or copper (Cu).

The ceramic electronic component may be at least one selected from the group consisting of a chip inductor, a chip bead, a power inductor, a chip antenna, and a chip LC filter.

According to another aspect of the present invention, there is provided a method of manufacturing a ceramic electronic component, the method including: preparing a plurality of magnetic layers; preparing a non-magnetic layer containing a compound represented by Chemical Formula Zn₁₋ₓCuₓMn₂O₄; forming internal electrode layers on the plurality of magnetic layers, respectively; forming a laminate by interposing the non-magnetic layer between the plurality of magnetic layers; forming a ceramic body by sintering the laminate; and forming external electrodes on the exterior of the ceramic body such that the external electrodes are electrically connected to the internal electrodes.

The compound may have a spinel-type crystal structure.

The compound may be prepared by mixing 40 to 50 mole % of manganese oxide (Mn₃O₄), 30 to 45 mole % of copper oxide (CuO), and 10 to 25 mole % of zinc oxide (ZnO).

The non-magnetic layer may further contain a sintering agent.

In the forming of the laminate, the non-magnetic layer may be interposed between the magnetic layers such that it is positioned in the middle thereof.

### BRIEF DESCRIPTION OF THE DRAWINGS

The above and other aspects, features and advantages of the present invention will be more clearly understood from the following detailed description taken in conjunction with the accompanying drawings, in which:

FIG. 1 is an external perspective view showing a ceramic electronic component according to an embodiment of the present invention;

FIG. 2 is a cross-sectional view of the ceramic electronic component, taken along line A-A′ of FIG. 1;

FIGS. 3A to 3D are views showing a process of manufacturing a ceramic electronic component according to another embodiment of the present invention;

FIG. 4 is a graph showing DC bias-TCL characteristics depending on the temperature of lamination-type power inductors according to Comparative Examples of the present invention; and

FIG. 5 is a graph showing DC bias-TCL characteristics depending on the temperature of lamination-type power inductors according to Inventive Examples of the present invention.

### DETAILED DESCRIPTION OF THE EMBODIMENTS

Embodiments of the present invention will now be described in detail with reference to the accompanying drawings. However, the embodiments of the present invention may be modified in many different forms and the scope of the invention should not be seen as being limited to the embodiments set forth herein. The embodiments of the present invention are provided so that those skilled in the art may more completely understand the present invention. In the drawings, the shapes and dimensions of elements may be exaggerated for clarity, and the same reference numerals will be used throughout to designate the same or like components.

A non-magnetic composition for a ceramic electronic component according to an embodiment of the present invention includes a compound represented by Chemical Formula Zn₁₋ₓCuₓMn₂O₄.

Generally, a non-magnetic layer is interposed between magnetic layers in order to obtain magnetic field-blocking effects when ceramic electronic components are manufactured. An existing non-magnetic layer may be formed of a material based on ZnCuFe₂0₄, and CuO may be added thereto for sintering bonding ability with the magnetic layer.

However, due to CuO added in order to secure sintering bonding ability, CuFe₂O₄ having magnetic characteristics is generated by the amount of Cu added, resulting in some magnetization behavior.

The above magnetization behavior may drop the magnetic field blocking performance with regard to magnetic field occurring when current is applied to the ceramic electronic component, and thus, DC bias characteristics may be degraded.

Further, in the case in which a staking-type power inductor is manufactured by using the non-magnetic layer formed of a material based on ZnCuFe₂0₄, the nickel (Ni) component contained in NiZnCuFe₂0₄ that is a magnetic material, may be diffused into the non-magnetic layer, and the zinc (Zn) component in the non-magnetic layer diffuses into the magnetic layers, and thus, the thickness of the magnetic layer be decreased.

As such, as the thickness of the non-magnetic layer is decreased, DC bias characteristics may be degraded.

Further, in the case in which a lamination-type power inductor is manufactured by using the non-magnetic layer formed of a material based on ZnCuFe₂0₄, delamination may occur due to the difference in a shrinkage ratio between the magnetic layer and the non-magnetic layer, and stress may occur within the power inductor.

Further, in the case in which a lamination-type power inductor is manufactured by using the non-magnetic layer formed of a material based on ZnCuFe₂0₄, DC bias-TCL characteristics may be degraded by being diffused in the non-magnetic layer.

Therefore, according to the present embodiment of the invention, a non-magnetic composition containing a compound represented by Chemical Formula Zn₁₋ₓCuₓMn₂O₄ is provided in order to solve the above defects.

The compound represented by Zn₁₋ₓCuₓMn₂O₄ is a complete non-magnetic composition having no magnetic characteristics, and thus has excellent magnetic flux blocking properties, leading to improvement in DC bias characteristics.

That is, magnetization at relatively high current may be suppressed by distributing paths for magnetic flux propagation by the coil inside the lamination-type power inductor, so that the change in an L value of inductance due to an application of current may be improved.

In addition, the non-magnetic composition according to the present embodiment of the invention may have a spinel-type crystal structure.

Generally, the non-magnetic layer formed of a material based on ZnCuFe₂0₄ has different crystal structure, lattice constant, and lattice structure from a spinel structure of ferrite used in the inductor body, which may cause mismatch therebetween, and thus, delamination defects may occur at the time of sintering of the inductor body.

However, according to the present embodiment of the invention, since the crystal structure of the non-magnetic composition has the same spinel-type crystal structure as the ferrite used in the inductor body, the occurrence of mismatch in the crystal structure, the lattice constant, and the lattice structure is relatively small, resulting in an improvement in delamination defects.

In addition, the temperature characteristics of the lamination-type power inductor may be improved, and thus bias-TCL characteristics depending on the temperature may be excellent.

Meanwhile, the compound may be prepared by mixing 40 to 50 mole % of manganese oxide (Mn₃O₄), 30 to 45 mole % of copper oxide (CuO), and 10 to 25 mole % of zinc oxide (ZnO).

Manganese oxide (Mn₃O₄) is not particularly limited, and for example, various oxides such as MnO, Mn₂O₃, or Mn₃O₄ may be used.

The content of manganese (Mn) may be based on the content thereof in the case of Mn₂O₃.

The contents of manganese oxide (Mn₃O₄), copper oxide (CuO) and zinc oxide (ZnO) are controlled as above, so that density and sintering shrinkage ratio of the non-magnetic layer correspond to those of NiZnCu ferrite, which is a material of the inductor body.

Due to this, delamination defects may be improved at the time of sintering of the inductor body, and DC bias characteristics may be improved. The thickness of the lamination-type power inductor may be decreased because similar DC bias characteristics may be obtained even in the case in which the thickness of the non-magnetic layer is decreased.

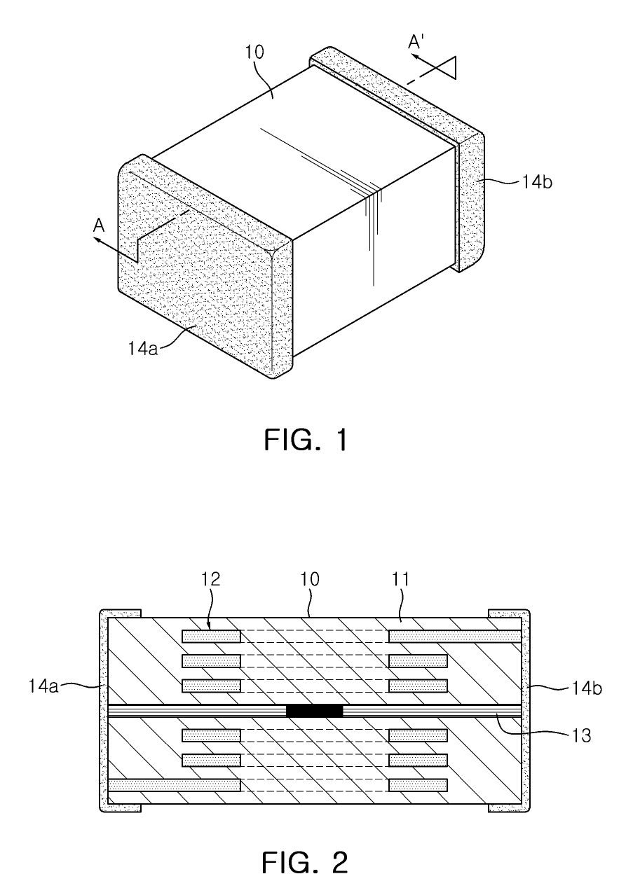

FIG. 1 is an external perspective view showing a ceramic electronic component according to an embodiment of the present invention.

FIG. 2 is a cross-sectional view of the ceramic electronic component, taken along line A-A′ of FIG. 1.

Hereinafter, a lamination-type power inductor will be described as an example of the ceramic electronic component.

Referring to FIGS. 1 and 2, a lamination-type power inductor according to the present embodiment of the invention may include: a ceramic body 10 having a plurality of magnetic layers 11 laminated therein; internal electrode layers 12 formed within the ceramic body 10; a non-magnetic layer 13 interposed between the magnetic layers 11 and containing a compound represented by Chemical Formula Zn₁₋ₓCuₓMn₂O₄; and external electrodes 14a and 14b formed on the exterior of the ceramic body 10 and electrically connected to the internal electrode layers 12.

In the present embodiment of the invention, the ceramic body 10 has a structure in which the non-magnetic layer 13 containing a compound represented by Chemical Formula Zn₁₋ₓCuₓMn₂O₄ is interposed between the magnetic layers 11. The compound exhibits complete non-magnetic characteristics as described above, so that a ceramic electronic component having improved DC bias characteristics may be provided.

In addition, the magnetic field is formed at the internal electrodes 12 when electricity is applied to the ceramic electronic component, but the magnetic field is completely blocked by the non-magnetic layer 13 of the present invention, and thus, excellent DC bias characteristics may be exhibited.

Since the other features of the non-magnetic composition are the same as those of the non-magnetic composition according to the present embodiment of the invention, descriptions thereof will be omitted.

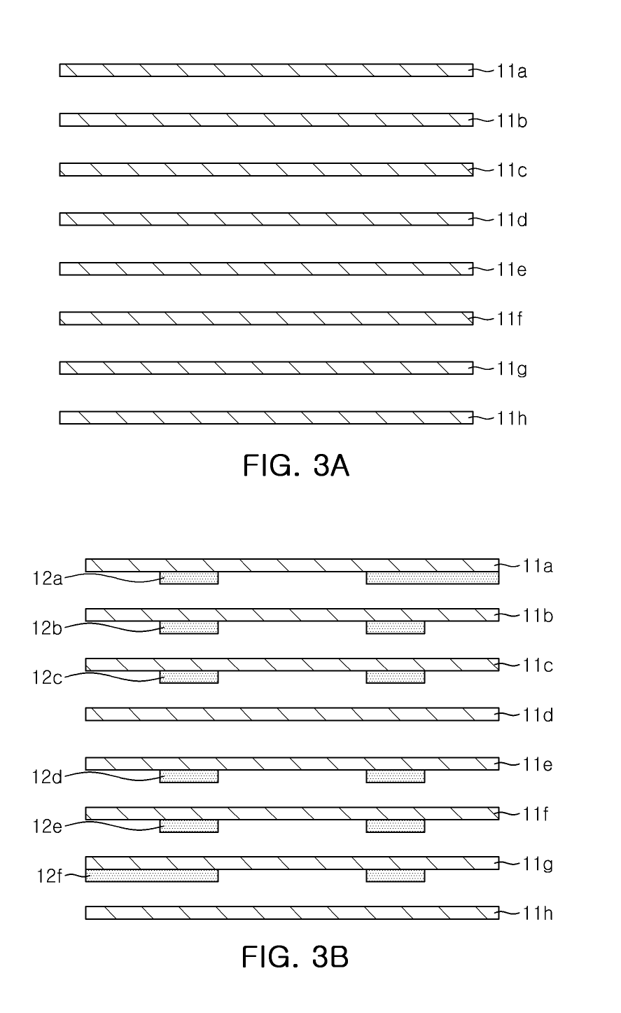

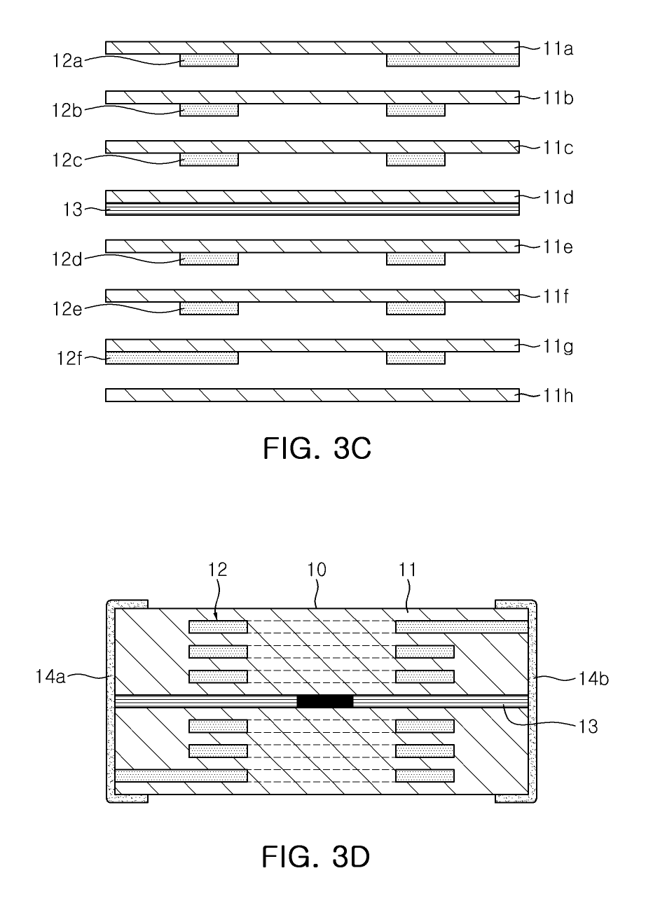

FIGS. 3A to 3D are views showing a process of manufacturing a ceramic electronic component according to another embodiment of the present invention.

Referring to FIGS. 3A to 3D, a method of manufacturing a ceramic electronic component according to the present embodiment of the invention may include: preparing a plurality of magnetic layers 11a, 11b, 11c, 11d, 11e, 11f, 11g, and 11h; preparing a non-magnetic layer 13 containing a compound represented by Chemical Formula Zn₁₋ₓCuₓMn₂O₄; forming internal electrode layers 12a, 12b, 12c, 12d, 12e, and 12f on the plurality of magnetic layers 11a, 11b, 11c, 11d, 11e, 11f, 11g, and 11h, respectively; forming a laminate by inserting the non-magnetic layer 13 between the plurality of magnetic layers 11a, 11b, 11c, 11d, 11e, 11f, 11g, and 11h; forming a ceramic body 10 by sintering the laminate; and forming external electrodes 14a and 14b on the exterior of the ceramic body 10 such that the external electrodes 14a and 14b are electrically connected to the internal electrodes 12.

First, as shown in FIG. 3A, the plurality of magnetic layers 11a, 11b, 11c, 11d, 11e, 11f, 11g, and 11h may be prepared.

The plurality of magnetic layers are only shown as an example, and the number of magnetic layers is not limited, and may be determined depending on the intended purpose of the ceramic electronic component.

The magnetic layers may be prepared by a method known in the art, and the material therefor is not particularly limited. For example, NiZnCuFe₂O₄ may be used as the material therefor.

In addition, the non-magnetic layer containing the compound represented by Zn₁₋ₓCuₓMn₂O₄ may be prepared, and the non-magnetic layer may be prepared by using the above-described non-magnetic composition.

Then, as shown in FIG. 3B, the internal electrode layers 12a, 12b, 12c, 12d, 12e, and 12f may be formed on the plurality of magnetic layers 11a, 11b, 11c, 11d, 11e, 11f, 11g, and 11h, respectively.

The internal electrode layers 12a, 12b, 12c, 12d, 12e, and 12f may be formed by a method known in the art, and a material therefor is not particularly limited. For example, the internal electrodes may be formed of at least one of Ag, Pt, Pd, Au, Cu, and Ni, or an alloy thereof.

In addition, according to the present embodiment of the invention, the internal electrode layers 12a, 12b, 12c, 12d, 12e, and 12f may be connected to each other by via electrodes (not shown), to thereby constitute a coil structure.

Then, as shown in FIG. 3C, the non-magnetic layer 13 may be interposed between the plurality of magnetic layers 11a, 11b, 11c, 11d, 11e, 11f, 11g, and 11h, to thereby form a laminate.

The non-magnetic layer 13 may be laminated between the plurality of magnetic layers 11a, 11b, 11c, 11d, 11e, 11f, 11g, and 11h. The position thereof is not particularly limited, and for example, the non-magnetic layer 13 may be positioned in the middle of the plurality of magnetic layers.

The non-magnetic layer 13 may be prepared by using the non-magnetic composition according to the present embodiment of the invention as described above, so that complete non-magnetic characteristics thereof may be exhibited.

Then, the laminate is fired to thereby form a ceramic body 10. Here, since the non-magnetic layer 13 has a spinel-type crystal structure, the non-magnetic layer 13 has good sintering bonding ability with the magnetic layers 11, and thus, delamination between the magnetic layer 11 and the non-magnetic layer 13, which may influence the yield of the ceramic electronic component, may be effectively prevented.

As shown in FIG. 3D, the external electrodes 14a and 14b are formed at the exterior of the ceramic body 10 such that they are electrically connected to the internal electrodes 12, to thereby manufacture the ceramic electronic component.

Hereinafter, the present invention will be described in detail with reference to Inventive Examples and Comparative Example, but they do not limit the scope of the present invention.

### INVENTIVE EXAMPLES

In each of Inventive Examples 1 to 4, a non-magnetic layer was prepared by using a mixture in which 45 mole % of manganese (Mn), 30, 35, 40, and 45 mole % of copper (Cu), and 10, 15, 20, and 25 mole % of zinc (Zn) , were respectively mixed.

A plurality of magnetic layers were prepared by using NiZnCuFe₂O₄ as a material therefor, and the non-magnetic layer was laminated between the magnetic layers, to thereby form a lamination-type power inductor.

### COMPARATIVE EXAMPLES

In each of Comparative Examples 1 to 5, a non-magnetic layer was prepared by using a mixture in which manganese (Mn), copper (Cu), and zinc (Zn) were mixed in amounts having a mole % outside of the numerical range of the present invention, respectively.

A plurality of magnetic layers were prepared by using NiZnCuFe₂O₄ as a material therefor, and the non-magnetic layer was laminated between the magnetic layers, to thereby form a lamination-type power inductor.

Each of the lamination-type power inductors according to Inventive Examples and Comparative Examples was fired at a temperature of 900° C.

Table 1 below compares the results of magnetic permeability, Q value, density, and shrinkage ratio measured at 1 MHz among the lamination-type power inductors manufactured according to the Inventive Examples and Comparative Examples.

TABLE 1

| | Composition | | | Magnetic | | | Shrink- |
|---|---|---|---|---|---|---|---|
| | (mole %) | | | per- | | Den- | age |
| | Zn | Cu | Mn | meability | Q | sity | ratio |
| Comparative | 50 | 0 | 50 | 3.58 | 20.89 | 3.17 | 5.20 |
| example 1 | | | | | | | |
| Comparative | 40 | 10 | 50 | 3.72 | 21.41 | 4.16 | 11.83 |
| example 2 | | | | | | | |
| Comparative | 40 | 12 | 48 | 3.86 | 18.82 | 4.33 | 12.75 |
| example 3 | | | | | | | |
| Comparative | 40 | 15 | 45 | 3.80 | 20.27 | 4.38 | 13.10 |
| example 4 | | | | | | | |
| Comparative | 32 | 20 | 48 | 3.80 | 20.90 | 4.44 | 12.85 |
| example 5 | | | | | | | |
| Comparative | 25 | 25 | 50 | 3.70 | 20.50 | 4.35 | 13.55 |
| example 6 | | | | | | | |
| Inventive | 25 | 30 | 45 | 3.90 | 30.50 | 4.98 | 15.00 |
| example 1 | | | | | | | |
| Inventive | 20 | 35 | 45 | 3.80 | 29.00 | 5.19 | 16.53 |
| example 2 | | | | | | | |
| Inventive | 15 | 40 | 45 | 3.80 | 29.40 | 5.28 | 17.55 |
| example 3 | | | | | | | |
| Inventive | 10 | 45 | 45 | 3.70 | 28.60 | 5.21 | 17.45 |
| example 4 | | | | | | | |

Referring to Table 1 above, it can be seen that in Comparative Examples 1 to 6 in which manganese (Mn), copper (Cu), and zinc (Zn) were mixed in terms of mole % contents outside of the numerical ranges of the present invention, respectively, densities thereof were 4.8 g/cc or smaller and shrinkage ratios thereof were 15% or lower.

Therefore, strength may be reduced and delamination may occur in the lamination-type power inductors manufactured by the Comparative Examples.

Whereas, in Inventive Examples 1 to 4, the densities thereof were 4.8 g/cc or greater and shrinkage ratios thereof were 15% or higher, and thus, delamination defects could be reduced while strength of the inductor is secured.

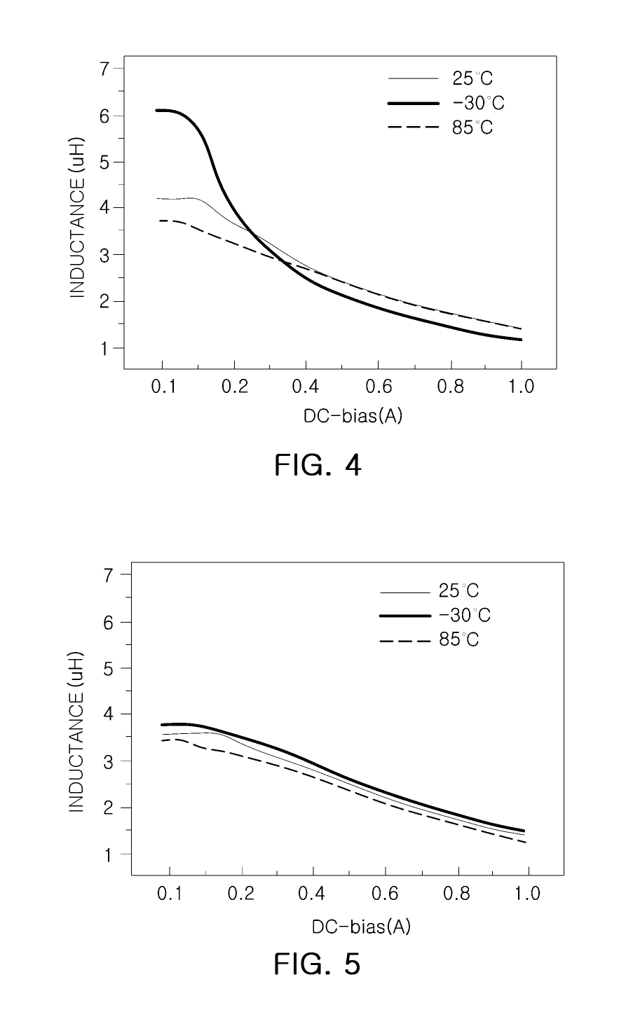

FIG. 4 is a graph showing DC bias-TCL characteristics depending on the temperature of lamination-type power inductors according to Comparative Examples of the present invention.

FIG. 5 is a graph showing DC bias-TCL characteristics depending on the temperature of lamination-type power inductors according to Inventive Examples of the present invention.

FIGS. 4 and 5 show DC bias-TCL characteristics depending on the temperature of lamination-type power inductors, which display results at 25° C., −30° C., and 85° C.

Referring to FIGS. 4 and 5, it can be seen that DC bias-TCL characteristics depending on temperature were more improved in the lamination-type power inductors according to the Inventive Examples of the present invention than in the lamination-type power inductors according to the Comparative Examples.

As set forth above, according to embodiments of the present invention, DC bias characteristics of the ceramic electronic component may be improved by employing the non-magnetic composition having no magnetic characteristics.

Further, magnetization at relatively high current may be suppressed by distributing the paths for magnetic flux propagation inside the coil, and thus, the change in inductance values may be improved and DC bias TCL characteristics depending on temperature may be improved.

Further, through control of a shrinkage ratio, the reduction in delamination defects, which may occur between the non-magnetic gap layer and the ceramic body, and the decrease in thickness of the chip may be achieved.

While the present invention has been shown and described in connection with the embodiments, it will be apparent to those skilled in the art that modifications and variations can be made without departing from the spirit and scope of the invention as defined by the appended claims.

What is claimed is:

1. A non-magnetic composition for a ceramic electronic component, the non-magnetic composition comprising a compound represented by Chemical Formula Zn₁₋ₓCuₓMn₂O₄.

2. The non-magnetic composition of claim 1, wherein the compound has a spinel-type crystal structure.

3. The non-magnetic composition of claim 1, wherein the compound is prepared by mixing 40 to 50 mole % of manganese oxide (Mn₃O₄), 30 to 45 mole % of copper oxide (CuO) , and 10 to 25 mole % of zinc oxide (ZnO).

4. A ceramic electronic component, comprising:
a ceramic body having a plurality of magnetic layers laminated therein;
internal electrode layers formed within the ceramic body;
a non-magnetic layer interposed between the magnetic layers and containing a compound represented by Chemical Formula Zn₁₋ₓCuₓMn₂O₄; and
external electrodes formed on the exterior of the ceramic body and electrically connected to the internal electrode layers.

5. The ceramic electronic component of claim 4, wherein the compound has a spinel-type crystal structure.

6. The ceramic electronic component of claim 4, wherein the compound is prepared by mixing 40 to 50 mole % of manganese oxide (Mn₃O₄), 30 to 45 mole % of copper oxide (CuO), and 10 to 25 mole % of zinc oxide (ZnO).

7. The ceramic electronic component of claim 4, wherein the internal electrode includes silver (Ag) or copper (Cu).

8. The ceramic electronic component of claim 4, wherein the external electrode includes silver (Ag) or copper (Cu).

9. The ceramic electronic component of claim 4, wherein the ceramic electronic component is at least one selected from the group consisting of a chip inductor, a chip bead, a power inductor, a chip antenna, and a chip LC filter.

10. A method of manufacturing a ceramic electronic component, the method comprising:
preparing a plurality of magnetic layers;
preparing a non-magnetic layer containing a compound represented by Chemical Formula Zn₁₋ₓCuₓMn₂O₄;
forming internal electrode layers on the plurality of magnetic layers, respectively;
forming a laminate by interposing the non-magnetic layer between the plurality of magnetic layers;
forming a ceramic body by sintering the laminate; and
forming external electrodes on the exterior of the ceramic body to allow the external electrodes to be electrically connected to the internal electrodes.

11. The method of claim 10, wherein the compound has a spinel-type crystal structure.

12. The method of claim 10, wherein the compound is prepared by mixing 40 to 50 mole % of manganese oxide (Mn₃O₄), 30 to 45 mole % of copper oxide (CuO), and 10 to 25 mole % of zinc oxide (ZnO).

13. The method of claim 10, wherein the non-magnetic layer further includes a sintering agent.

14. The method of claim 10, wherein in the forming of the laminate, the non-magnetic layer is interposed between the magnetic layers.
